(19) United States
(12) Patent Application Publication
(10) Pub. No.: US 2014/0368826 A1
(43) Pub. Date: Dec. 18, 2014

(54) CAVITY ENHANCED SPECTROSCOPY

(71) Applicants: James E. Abbott, JR., Albany, OR (US); Alan T. Davis, Philomath, OR (US)

(72) Inventors: James E. Abbott, JR., Albany, OR (US); Alan T. Davis, Philomath, OR (US)

(73) Assignee: Hewlett-Packard Development Company, L.P., Houston, TX (US)

(21) Appl. No.: 14/376,078

(22) PCT Filed: Apr. 25, 2012
(86) PCT No.: PCT/US12/34881

§ 371 Date: Jul. 31, 2014

(51) Int. Cl. G01N 21/25; H01L 31/173; G01J 3/26

(52) U.S. Cl. CPC G01N 21/255; G01J 3/26; H01L 31/173; G01N 2201/068
USPC 356/454; 438/25

(57) ABSTRACT

The present disclosure describes cavity enhanced spectroscopy (CES) apparatuses, and systems, and methods of forming the same. An example of a CES apparatus includes a first partial reflector, an optical cavity to expose a sample to electromagnetic radiation below the first partial reflector, and a semiconductor wafer with the first partial reflector and the optical cavity formed thereon.

### BACKGROUND

Molecules can be identified using optical spectroscopy. When molecules are placed within a cavity with reflective elements (e.g., an optical cavity) an output may be produced such that a particular signal may be markedly increased through resonance, which contributes to cavity enhanced spectroscopy (CES). The increased signal can include a characteristic that is uniquely identifiable to a particular molecule.

### BRIEF DESCRIPTION OF THE DRAWINGS

FIG. 1 illustrates an example of a side-view schematic of a portion of a CES apparatus including first and second partial reflectors according to the present disclosure.

FIG. 2 illustrates an example of a side-view schematic of a portion of a CES apparatus including a complete reflector according to the present disclosure.

FIG. 3 illustrates an example of a CES apparatus with an optical cavity formed according to the present disclosure.

FIG. 4 is a block diagram illustrating an example of a portion of a CES apparatus according to the present disclosure.

### DETAILED DESCRIPTION

Examples of the present disclosure include apparatuses, systems and methods for cavity enhance spectroscopy (CES). An example of a CES apparatus includes a first partial reflector, an optical cavity to expose a sample to electromagnetic radiation below the first partial reflector, and a semiconductor wafer with the first partial reflector and the optical cavity formed thereon.

Apparatuses, systems, and methods that identify molecules by optical spectroscopy, as described herein, have a wide range of applications in both the chemical and biomolecular areas that can benefit from detection of particular molecules. As optical spectroscopy improves, the ability to detect particular molecules becomes increasingly possible. However, as such technology increases in both complexity and number of applications, so too do the challenges of reproducibility and maintaining signal intensity.

As the level of enhancement increases, effects of errors (e.g., improper sample production, unintended variations in the dimensions of an optical cavity and/or its components, and others resulting in non-uniform signal production) also may be amplified. These errors may become notable when trying to reliably reproduce outputs (e.g., signals). Reliable signal enhancement may depend upon on an ability to create an increased signal that has both high intensity and high reproducibility. Additionally, high resolution tools for optically detecting chemical species and/or material properties tend to be large, expensive, and/or have limited mobility, thereby limiting them to laboratory applications. In many situations, it is desirable to optically detect chemical species outside of a laboratory setting.

To realize such goals, a small optical cavity can be utilized. However, a potential difficulty is that as the size of the optical cavity decreases, reliable formation and reproducible implementation of a CES apparatus utilizing the optical cavity may become increasingly difficult. Accordingly, maintaining consistent dimensions and implementation of a small optical cavity can affect enhancement of the signals.

Optical cavities used in conjunction with an electromagnetic radiation detector, as described herein, can contribute to high signal intensity and reproducibility. Further, the optical cavities can be incorporated directly onto a semiconductor wafer because the optical cavities can be small, among other considerations. Optical cavities may be readily formed as described herein.

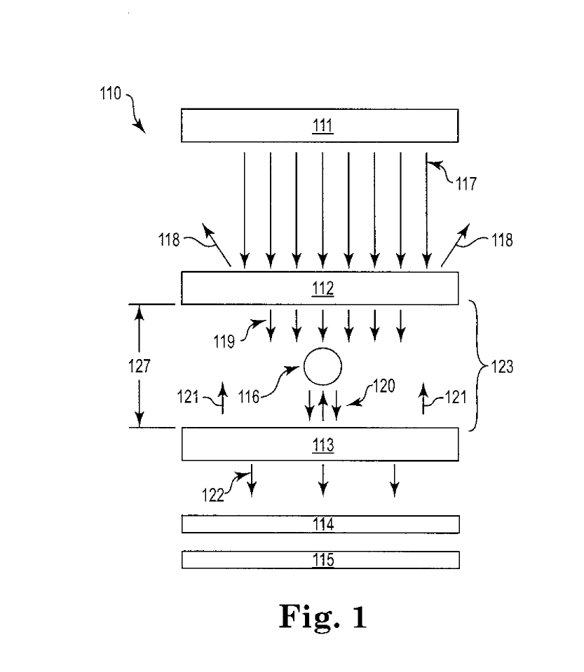

FIG. 1 illustrates an example of a side-view schematic of a portion of a CES apparatus including first and second partial reflectors according to the present disclosure. In the following Detailed Description and Figures, some features are grouped together in a single example for the purpose of streamlining this disclosure. This manner of presentation is not to be interpreted as reflecting an intention that the disclosed examples require more features (e.g., elements and/or limitations) than are expressly recited in the claims of the present disclosure. Rather, as the following claims reflect, inventive subject matter may require less than all features of a single disclosed example. Hence, the following claims are hereby incorporated into the Detailed Description, with each claim standing on its own merit as a separate example.

As illustrated in FIG. 1, an example of a CES apparatus 110 includes a first partial reflector 112, an optical cavity 123 below the first partial reflector 112, and a semiconductor wafer 115 with the first partial reflector 112 and the optical cavity 123 formed thereon. An electromagnetic radiation source 111 can be included for emitting electromagnetic radiation into the optical cavity 123. In various examples, a second partial reflector 113 can be included to transmit a portion of the electromagnetic radiation to a detector 114 that can detect the portion of the electromagnetic radiation.

As illustrated in FIG. 1, the CES apparatus 110 can include the electromagnetic radiation source 111 emitting electromagnetic radiation (e.g., an input electromagnetic radiation 117 and/or introduced electromagnetic radiation 119) into the optical cavity 123 at an angle that is substantially normal (e.g., perpendicular) to the first partial reflector 112 and/or the second partial reflector 113. In some examples, the second partial reflector 113 is positioned below the first partial reflector 112 and the optical cavity 123, as illustrated in FIG. 1. However, the present disclosure is not limited to such a configuration. That is, the angle and orientation of the electromagnetic radiation source 111, the first partial reflector 112, the second partial reflector 113, the detector 114, and/or the semiconductor wafer 115 can be varied with respect to one or another in a manner that is conducive to reliable production of a signal. For example, the first partial reflector 112 can be substantially parallel to the electromagnetic radiation source 111 and/or orthogonal to the input electromagnetic radiation 117 emitted from the electromagnetic radiation source 111.

In the detailed description of the present disclosure, reference is made to the accompanying drawings that form a part hereof and in that is shown by way of illustration examples of how the disclosure may be practiced. These examples are described in sufficient detail to enable those of ordinary skill in the art to practice the examples of this disclosure. It is to be understood that other examples may be utilized and that material variations and/or structural changes may be made without departing from the scope of the present disclosure. Further, where appropriate, as used herein, “for example” and “by way of example” should each be understood as an abbreviation for “by way of example and not by way of limitation”.

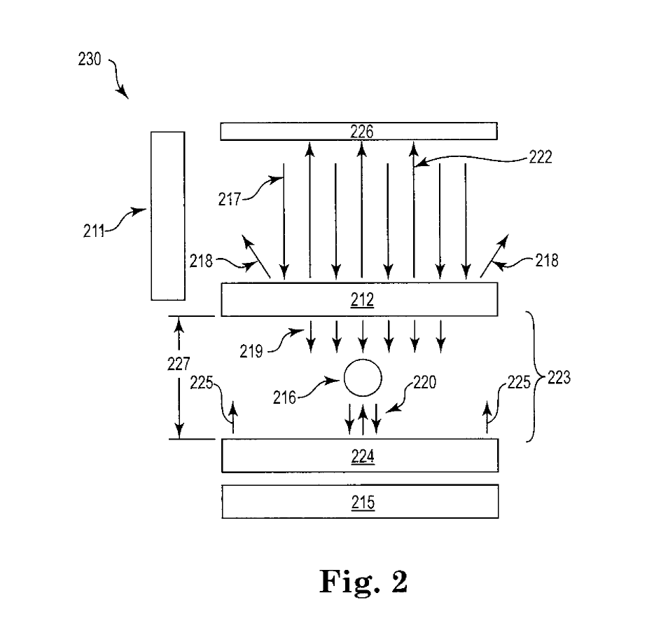

The figures herein follow a numbering convention in that the first digit or digits correspond to the drawing figure number and the remaining digits identify an element or component in the drawing. Similar elements or components between different figures may be identified by the use of similar digits. For example, 104 may reference element “104” in FIG. 1, and a similar element may be referenced as “204” in FIG. 2. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure and should not be taken in a limiting sense.

Unless otherwise indicated, all numbers expressing ranges and dimensions, and so forth, used in the specification and claims are to be understood as being modified in all instances by the terms “substantially” or “about”. Accordingly, unless indicated to the contrary, the numerical parameters set forth in the following specification and attached claims are approximations that may vary depending upon the properties sought to be obtained.

As illustrated in FIG. 1, in some examples, the input electromagnetic radiation 117 can be reflected by the first partial reflector 112 as a first reflected electromagnetic radiation 118. That is, a portion of the input electromagnetic radiation 117 can be reflected away, by the first partial reflector 112, from entering the optical cavity 123 as the first reflected electromagnetic radiation 118. In addition, a portion of the input electromagnetic radiation 117 can pass through the first partial reflector 112 to become the introduced electromagnetic radiation 119 inside the optical cavity 123. The portion entering the first partial reflector 112 and/or the optical cavity 123 can, in some examples, be varied by changing the configuration and/or orientation of the optical cavity 123, as described herein. In some examples, the introduced electromagnetic radiation 119 transmitted into the optical cavity 123 can be substantially 100% of the input electromagnetic radiation 117

In some examples, a portion of the electromagnetic radiation (e.g., introduced electromagnetic radiation 119) can encounter the second partial reflector 113 and be reflected away from leaving the optical cavity 123 as a second reflected electromagnetic radiation 121. By way of example, the second partial reflector 113 can reflect substantially 99.99% (e.g., having absorption and/or transmission losses of 0.01% or less) of electromagnetic radiation within the optical cavity 123 as the second reflected radiation 121. In various examples, the first partial reflector 112 can reflect a portion of electromagnetic radiation within the optical cavity 123. This can include the second reflected electromagnetic radiation 121 reflected by the second partial reflector 113 and/or not absorbed by the sample 116. By way of example, the first partial reflector 112 can reflect (e.g., backscatter) substantially 99.99% (e.g., having absorption and/or transmission losses of 0.01% or less) of the electromagnetic radiation within the optical cavity 123 as a third reflected electromagnetic radiation (not shown).

Accordingly, the first partial reflector 112 and the second partial reflector 113, in some examples, can cause the electromagnetic radiation (e.g., the introduced electromagnetic radiation 119) within the optical cavity 123 to be reflected many times within the optical cavity 123. The electromagnetic radiation within the optical cavity 123 can impact the sample 116 and become an impacted electromagnetic radiation 120. In some examples, a portion of the impacted electromagnetic radiation 120 can be absorbed upon impacting the sample 116. In addition, in some examples, a portion of the impacted electromagnetic radiation 120 can be reflected upon impacting the sample 116. In various examples, multiple reflections of the electromagnetic radiation (e.g., the impacted electromagnetic radiation 120 and/or second electromagnetic radiation 121) within the optical cavity 123 have an opportunity to impact and/or be absorbed by the sample 116 multiple times, which can increase a probability of portions of the electromagnetic radiation being absorbed by the sample 116. In some examples, electromagnetic radiation can pass through a partial reflector (e.g., second partial reflector 113) such that residual electromagnetic radiation 122 can be detected by the detector 114.

As described herein, the residual electromagnetic radiation 122 can be defined as an amount of electromagnetic radiation within and/or output from the optical cavity 123 following exposure of the sample to and/or absorption by the sample of initially introduced electromagnetic radiation 119. In addition, in various examples, a baseline amount of output electromagnetic radiation can be detected, as described herein, corresponding to either a vacant optical cavity 123 (e.g., without a sample therein) and/or a control substance (e.g., with known absorption characteristics) within the optical cavity 123. That is, in some examples, the residual electromagnetic radiation 122 detected by the detector 114 can be compared to electromagnetic radiation detected by the detector 114 with the vacant optical cavity and/or with the control substance in the optical cavity to determine an adsorption spectrum for the sample 116. Such a comparison can, in some examples, identify a rate of absorption of the electromagnetic radiation within the optical cavity 123 by the sample 116, which can correspond to a particular composition and/or concentration of the sample 116.

As described herein, the walls of the optical cavity can be partially reflective, completely reflective, and/or combinations thereof, to the electromagnetic radiation within the optical cavity 123. In some examples, the cavity walls can include various combinations of the first partial reflector 112, the second partial reflector 113, and/or a complete reflector 224, as shown in FIG. 2. Accordingly, the first partial reflector 112, the second partial reflector 113, and/or the complete reflector 224 can contribute to creating a relatively uniform electromagnetic radiation field inside the optical cavity 123. That is, the optical cavity 123 can act as an electromagnetic radiation accumulator, ensuring that the electromagnetic radiation within the optical cavity 123 repeatedly reflects within the optical cavity, until it is either diffuses through, or is absorbed by, the walls, impacts the sample 116, or leaves the optical cavity 123 by passing through the first partial reflector 112 and/or the second partial reflector 113. In some examples, the walls of the optical cavity 123 can form smooth parallel edges, for instance, forming a Fabry-Pérot resonator.

As described herein, electromagnetic radiation can be resonant within the optical cavity. That is, the electromagnetic radiation (e.g., light) can include a frequency that causes the electromagnetic radiation within the optical cavity (e.g., 123) to oscillate at greater amplitude at a particular frequency or frequencies than at other frequencies and/or increases transmissibility of the electromagnetic radiation through the first (e.g., 112) and/or the second partial reflector (e.g., 113). As used herein, transmissibility can be defined as the portion of electromagnetic radiation from an electromagnetic radiation source that passes through the first and/or the second partial reflectors. In some examples, operating at a resonance frequency can increase the transmissibility of the first partial reflector (e.g., 112) and/or second partial reflector (e.g., 113).

Different resonance frequencies can be produced by altering the configuration of and/or distance between the one or more partial reflectors, complete reflector, and/or cavity walls associated with the optical cavity. As such, discrete resonance frequencies can be produced. In various examples, the first partial reflector (e.g., 112) and another reflector (e.g., second partial reflector 113) on opposite sides of the optical cavity (e.g., 123) form a resonance chamber for electromagnetic radiation emitted by one or a number of electromagnetic radiation sources (e.g., electromagnetic radiation source 111).

The amount of electromagnetic radiation reflected in any of the above-described examples of the optical cavity 123 can be sufficient to contribute to impacting the sample 116 with electromagnetic radiation. In some examples, this translates to a measurable signal (e.g., at the detector 114) following impact (e.g., absorption) of a fraction of electromagnetic radiation with the sample 116. Thus, the thickness and/or the nature of the material of the walls of the optical cavity 123 and/or a coating applied to the walls of the optical cavity 123 can be chosen to achieve an adequate signal in the spectral range of interest.

In various examples, the electromagnetic radiation source 111 can be one or a plurality of devices (e.g., electromagnetic radiation sources), for example, light emitting diodes (LEDS), lasers, hot filaments, gamma and/or X-ray radiation sources, and/or other suitable sources. As described herein, the electromagnetic radiation source 111 can, in some examples, be either a pulse laser or a continuous laser. Pulsed operation of a laser (e.g., the pulse laser), as described herein, refers to any laser not operated as continuous wave (e.g., the continuous laser), such that photons can be applied in pulses of a defined duration at a defined repetition rate. In some examples, the pulse laser can be used in conjunction with a detection device (e.g., detector 114) to create and/or detect a signal of interest (e.g., the residual electromagnetic radiation). The residual electromagnetic radiation can correspond to a rate of absorption of the electromagnetic radiation (e.g., the introduced radiation 119) in the optical cavity 123 (e.g., by the sample 116). Alternatively, continuous lasers can emit an electromagnetic radiation beam whose output can be substantially constant over time. Operating in continuous and/or pulse mode can satisfy applications as described herein.

In some examples, the lasers can be multi-mode (e.g., having multiple outputs based on a variety of selectable output parameters). As used herein, a multi-mode laser can account for various factors, for example, a size and shape of the optical cavity, the particular material and configuration of the sample, the material, shape, and orientation of the first and/or second partial reflectors, among other considerations. Based on such considerations, the laser can be adjusted, for example, to emit a wavelength of a particular frequency or range of frequencies.

In some examples, high powered electromagnetic radiation (e.g., laser radiation) can be expanded prior to reaching the sample by an electromagnetic radiation expanding element. This can avoid unnecessarily high local intensity on any portion of the sample and/or can contribute to a relatively uniform production of an electromagnetic radiation field. As used herein, an electromagnetic radiation expanding element can be any device or system that reduces power density of introduced electromagnetic radiation at any given point on the sample, in comparison to that from the total input power that would otherwise be provided to the optical cavity 123. By way of example, a radiation expanding element can comprise a lens or an optical fiber designed to expand the cross-sectional area of an electromagnetic radiation beam and/or produce an expanded beam having a lower power density per unit of surface area than the non-expanded beam.

Alternatively or in addition, in some examples, a concentrating device can be employed to concentrate and/or alter (e.g., shape) the introduced electromagnetic radiation from the number of electromagnetic radiation sources. By way of example, the concentrating device can include one or more diffractive and/or digital optical devices positioned in the pathway of the number of electromagnetic radiation sources (e.g., lasers) such that one or more diffractive and/or digital optical devices cause converging of electromagnetic radiation from the number of electromagnetic radiation sources, for example into a collimated stream (e.g., a laser beam).

In some examples, a number of devices (e.g., optical fibers) can allow for simultaneous delivery of electromagnetic radiation to multiple points outside, and consequently within, the optical cavity. In some examples, the number of devices can be coupled (e.g., optically) to the number of electromagnetic radiation sources.

As described herein, a variety of materials can be used in the formation of the CES apparatus to provide a range of physical characteristics, such as reflectivity, transmissibility, and/or mechanical strength, among others. In some examples, a partial reflector can be a film and/or a partial transmission dielectric (e.g., a dielectric material). In some examples, the partial reflector can be a metal. In some examples, the partial reflector can be a non-metal material. In some examples, the partial reflector can be coated with a partial transmission dielectric material. In some examples, the partial reflector can take the form of a sheet or a three-dimensional object of various shapes. By way of example, a first partial reflector, a second partial reflector, and/or a complete reflector can be a variety of shapes including but not limited to elliptical, round, flat, curved, square, rectangular, among others.

The partially reflective material (e.g. the first partial reflector and/or second partial reflector) can include aluminum, silver, gold, among other suitably reflective metals, and/or combinations thereof. The partial transmission dielectric material can include titanium dioxide, silicon dioxide, niobium oxide, among other suitable dielectric materials, and/or combination thereof. In some examples, portions of the apparatus (e.g., the dielectric material) can be formed from a transparent material, for example, silicon dioxide, among others. In some examples, the second partial reflector 113 can be constructed of the same shape and/or material, as described herein, as the first partial reflector 112. Alternatively, the second partial reflector 113 can be constructed of a shape and/or material, as described herein, that are dissimilar to the first partial reflector 112.

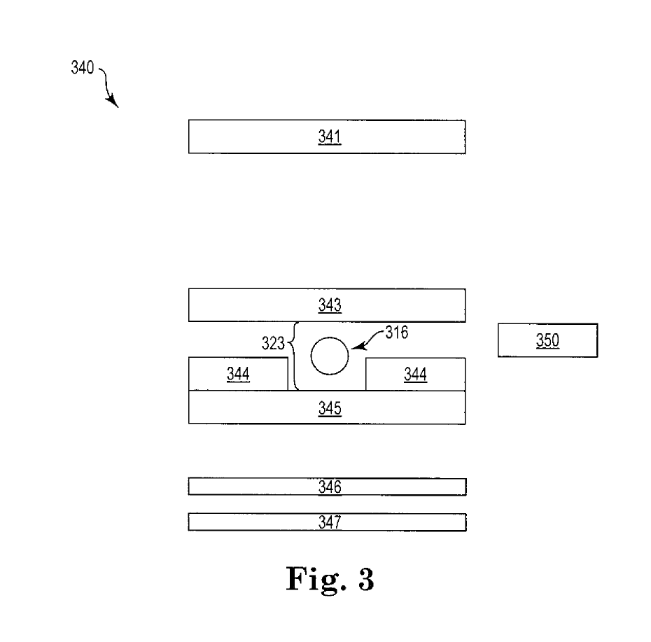

As described herein, the sample 116 can be in gas, liquid, solid, and/or plasma phases. The sample 116 can be created as part of the optical cavity or can be inserted into a previously formed optical cavity 123. That is, in some examples, the sample 116 can be placed inside of the optical cavity 123, for example, by a sample delivery device 350, as illustrated in FIG. 3. Sample orientation within the optical cavity can be varied according to the nature of the sample and/or the signal sought, as detailed herein.

As described herein, the optical cavity 123 can be a space that provides a volume for exposure of the sample 116 to electromagnetic radiation, as described herein. The optical cavity 123 can be used in conjunction with standard spectroscopic detection methods, for example, fluorescence, absorption, and/or Raman detection. In various examples, the optical cavity 123 can be defined, at least in part, by a distance 127 between the first partial reflector 112 and the second partial reflector 113. Similarly, as illustrated in FIG. 2 and described herein, the optical cavity 223 can be defined, at least in part, by a distance 227 between the first partial reflector 212 and the complete reflector 224. For example, the distance can be in a range of from substantially 5 nanometers (nm) to substantially 0.5 centimeters (cm).

Optical spectroscopy utilizing the optical cavity, as described herein, can be used to characterize (e.g., detect) a chemical composition of the sample 116 (e.g., identify a particular chemical or chemicals), measure a concentration of one or more chemicals in the sample 116, or both. By way of example, the sample 116 can be a biological sample (e.g., body fluids, tissues, or other organic samples) or any other sample, such as but not limited to, food, plastics, explosives, poisons, carcinogen, petroleum products, vapors of various substances, liquids of various substances, and the like.

In some examples, the optical cavity 123 can be configured as a multi-sensor capable of detecting one or more properties (e.g., fluid composition, pressure, mass, temperature, density, and/or other physical properties) of a sample 116. The multi-sensor capability can aid in characterizing the chemical composition of the sample 116, measuring the concentration of one or more chemicals in the sample 116, or both.

Detection of signals characterizing properties, such as those described herein, can be accomplished by the detector 114. The detector 114 can be any device capable of detecting a suitable output (e.g., electromagnetic radiation) and/or property. The detector 114 can be, but is not limited to, a photo detector array such as a linear diode (e.g., photodiode) array, a charge coupled device (CCD), a photomultiplier, and/or fiber optic device. The thickness and/or the nature of the materials for forming the detector can be chosen to achieve an adequate signal in the spectral range of interest. In various examples, the electromagnetic radiation source 111 (e.g., an LED) can also act as the detector.

In some examples, the detector 114 can include a fiber optic device coupled to a photo multiplier tube. In some examples, the detector 114 can be directly coupled (e.g., optically) to the optical cavity 123. Alternatively or in addition, the detector 114 in some examples can be indirectly linked to the optical cavity 123, for example, by a fiber optic device.

In some examples, the optical cavity 123 can be orientated to reduce the amount of background noise at the detector 114. That is, the design of the optical cavity 123 can be configured to reduce the amount of radiation other than the electromagnetic radiation sought for detection. As such, this can increase the signal to background noise ratio and/or the overall system sensitivity.

By way of example, reducing background radiation can include the introduced electromagnetic radiation 119 being transmitted into the optical cavity 123 outside a detection range of the detector 114. Alternatively or in addition, in some examples, physical elements can filter electromagnetic radiation in order to obtain the electromagnetic radiation for detection prior to detection by the detector 114. For example, screens, gratings, waveguides, among others, can be used to separate intended electromagnetic radiation for detection (e.g., control polarization of the detected electromagnetic radiation) from background radiation (e.g., the input electromagnetic radiation 119). In some examples, detection can be enhanced by allowing electromagnetic radiation to enter and/or leave the optical cavity 123 slightly off axis (e.g., at an angle other than 90 degrees to the first partial reflector).

Alternatively or in addition, reduced background noise can be achieved by using an electromagnetic radiation scattering baffle to divide the optical cavity into a plurality of separate sub-cavities (e.g., chambers). These chambers can be arranged in parallel or in series with respect to a sample flow. The baffles can, in various examples, be used to reduce direct coupling of introduced electromagnetic radiation 119 with the detector 114, thus reducing background signals caused by electromagnetic radiation that has not interacted with the sample 116.

In various examples, one or more devices (e.g., optical fibers) can allow for simultaneous collection of the intended electromagnetic radiation from multiple points within the optical cavity 123. In various examples, one or more devices (e.g., optical fibers) can be coupled (e.g., optically) to the detector 114 located external and/or separate from the optical cavity 123. In various examples, the detector 114 can be a plurality of detectors.

In some examples, the detector 114 can be linked to a data collection unit containing electronic components for extracting signals from the detector and/or an analogue to digital converter for presentation of data in a digital form. The digitized data from the data collection unit can be transferred to a data processing unit, which can perform data preprocessing, processing, and/or can prepare data for presentation. The results can be further processed, locally stored in memory bank, transferred to external users for further processing, and/or presented to an operator by means of a user interface. In some examples, collection of signals (e.g., data) at the detector 114 can be used to provide for a processor to characterize the chemical composition of one or more molecules, among other characteristics, as described herein.

FIG. 2 illustrates an example of a side-view schematic of a portion of a CES apparatus including a complete reflector according to the present disclosure. FIG. 2 illustrates a CES apparatus 230 where the detector 226 can be positioned above a first partial reflector 212. Additionally, FIG. 2 illustrates that a complete reflector 224 can be positioned below a first partial reflector 212 and an optical cavity 223. In some examples, an optical means (e.g., a waveguide and/or a material positioned at a Brewster's angle) can alter one or more characteristics (e.g., polarization and/or transmission direction) of input electromagnetic radiation 217 emitted by an electromagnetic radiation source 211 to encounter the first partial reflector 212 in an intended manner (e.g., substantially at an intended angle). Alternatively or in addition, a quarter wave plate can be positioned such that the input electromagnetic radiation 217 can be altered to an intended polarization and/or transmission direction prior to encountering the first partial reflector 212. However, as described herein in reference to FIG. 1, the present disclosure is not limited to such a configuration.

In various examples, a portion of input electromagnetic radiation 217 from the electromagnetic radiation source 211 can encounter the first partial reflector 212 and be reflected away from entering the optical cavity 223 as a first reflected electromagnetic radiation 218. In addition, a portion of the input electromagnetic radiation 217 can pass through the first partial reflector 212 to become introduced electromagnetic radiation 219 within the optical cavity 223. FIG. 2 illustrates, by way of example, the CES apparatus 230 having the introduced electromagnetic radiation 219 transmitted into the optical cavity 223 at an angle that is substantially orthogonal to the first partial reflector 212 and/or the complete reflector 224. However, as described herein, the present disclosure is not limited to such a configuration.

In various examples, electromagnetic radiation (e.g., the introduced electromagnetic radiation 219) can be reflected by the complete reflector 224, as a second reflected radiation 225. By way of example, the complete reflector 224 can reflect (e.g., backscatter) substantially 100% of the electromagnetic radiation (e.g., the introduced electromagnetic radiation 219) within the optical cavity 223. The complete reflector 224 can be one or more metals and/or a dielectric material, as described herein. In various examples, a sample delivery device (e.g., as shown at 350 in FIG. 3) can deliver a sample 216 to the optical cavity 223.

In some examples, electromagnetic radiation (e.g., the second reflected radiation 225) can be reflected (e.g., backscattered) by the first partial reflector 212. By way of example, the first partial reflector 212 can reflect (e.g., backscatter) substantially 99.99% the electromagnetic radiation (e.g., the second reflected radiation 225) within the optical cavity 223 as a third reflected electromagnetic radiation (not shown). In some examples, that the CES apparatus can include a semiconductor wafer 215 with the first partial reflector 212, the complete reflector 224, and the optical cavity 223 formed thereon.

Accordingly, the first partial reflector 212 and the complete reflector 224, in some examples, can cause the electromagnetic radiation (e.g., the introduced electromagnetic radiation 219) within the optical cavity 223 to be reflected multiple times within the optical cavity 223. The electromagnetic radiation within the optical cavity 223 can impact the sample 216 and become impacted electromagnetic radiation 220. As detailed in reference to FIG. 1, a portion of the impacted electromagnetic radiation 220 can be absorbed or reflected upon impacting the sample 216. In some examples, multiple reflections of the electromagnetic radiation (e.g., the impacted electromagnetic radiation 220 and/or the second reflected radiation 225) within the optical cavity 223 give an opportunity to impact and/or be absorbed by the sample 216 multiple times, which can increase the probability of portions of the electromagnetic radiation being absorbed by the sample 216. In various examples, as described herein, electromagnetic radiation can pass through a partial reflector (e.g., the first partial reflector 212) such that residual electromagnetic radiation 222 can be detected by a detector 226, as described herein.

By way of example, forming the CES apparatus, as described herein, can include forming suitable electrical circuitry by suitable techniques. The CES apparatus can be formed using techniques such as chemical/mechanical polishing, spin coating, and/or thin film deposition techniques (e.g., microelectromechanical systems (MEMS)). By way of example and not by way of limitation, a photodiode can be formed (e.g., using MEMS) in combination with a wafer of suitable thickness. In some examples, the photodiode can include the detector 114 and the semiconductor wafer 115. The semiconductor wafer 115 can, in various examples, include an electrically conducting, semi-conducting, and/or an electrically insulating material (e.g., glass, polymer, and/or silicon, among other materials) to provide structural stability for the CES apparatus and/or suitable properties (e.g., semi-conductivity). In various examples, the semiconductor wafer 115 with the with the first partial reflector 123 and/or the optical cavity 123 formed thereon can be in a range of from substantially 0.5 millimeters (mm) to substantially 10 mm in width and length.

FIG. 3 illustrates an example of a CES apparatus with an optical cavity formed according to the present disclosure. As illustrated in FIG. 3, a CES apparatus 340, can, in some examples, include an electromagnetic radiation source 341, a sample delivery device 350, and a detector 346. Other elements illustrated in FIG. 3 include a first substrate 345 that can be formed on an upper surface of a semiconductor wafer 347 and/or on an upper surface of the detector 346 formed on the upper surface of the semiconductor wafer 347. In some examples, forming the first substrate 345 can include forming a dielectric material (e.g., a first dielectric) on the semiconductor wafer 347. In various examples, forming the first substrate 345 can include forming (e.g., forming a layer of) a partially reflective material (e.g., a second partial reflector) on an upper surface of the dielectric material (e.g., the first dielectric) in order to create a suitable degree of reflectivity. A dielectric material (e.g., a second dielectric), such as those described herein, can, in some examples, be formed on an upper surface of the partially reflective material (e.g., the second partial reflector). This can separate the partially reflective material (e.g., the second partial reflector) from a sample to be located in an optical cavity 323.

As illustrated in FIG. 3, the optical cavity 323 can be formed above the first substrate 345. In some examples, forming the optical cavity 323 can include forming a spacer 344 on the upper surface of the first substrate 345 and/or bonding the spacer 344 to an upper surface of the first substrate 345. Bonding can include utilizing heat, adhesive, and/or pressure. In some examples, the spacer 344 can be made of a plurality of spacers positioned on the upper surface of the first substrate 345. The spacer can be any suitable material that provides suitable properties (e.g., reflectivity, support, etc.) for forming the optical cavity 323, as described herein.

Alternatively or in addition, a sacrificial layer (not shown) can be formed (e.g., by spin coating) to substantially fill, and to consequently be removed at least in part, to form a space (e.g., the optical cavity 323). In some examples, the space can be between a first partial reflector and the second partial reflector, as described herein. For example, the sacrificial layer can be amorphous silicon or a polymer, among other suitable materials. In some examples, the sacrificial layer can be smoothed (e.g., by chemical and/or mechanical polishing). In various examples, the sacrificial layer can be at least partially removed to form the optical cavity 323. The at least partial removal of the sacrificial layer can be accomplished through a variety of techniques. By way of example, the removal can be accomplished by wet and/or dry etching (e.g., chemical mechanical polishing), among other techniques.

As illustrated in FIG. 3, a second substrate 343 can be formed above the optical cavity 323. In some examples, forming the second substrate 343 can include a dielectric material (e.g., a third dielectric), such as those detailed herein, formed on an upper surface of the sacrificial layer (not shown) and/or the spacer 344. In various examples, forming the second substrate 343 can include forming (e.g., forming a layer of) a partial reflective material (e.g., a first partial reflector) on an upper surface of the dielectric material (e.g., the third dielectric) in order to create a suitable degree of reflectivity. In some examples, the dielectric material (e.g., a fourth dielectric) can be formed on the partially reflective material (e.g., the first partial reflector).

As described herein, the sample delivery device 350 can be a suitable means for introducing the sample into the optical cavity 323. In various examples, the sample delivery device 350 can include a mechanical structure (e.g., an arm) for physically moving the sample 316 into the optical cavity 323, air and/or pressure devices for propelling the sample 316 into the optical cavity 323, and/or other suitable means for introducing the sample 316 into the optical cavity 323. In some examples the sample delivery device 350 can be automated (e.g., computer controlled). Alternatively or in addition, delivering the sample 316 into the optical cavity 323 by the sample delivery device 350 can be performed by a user.

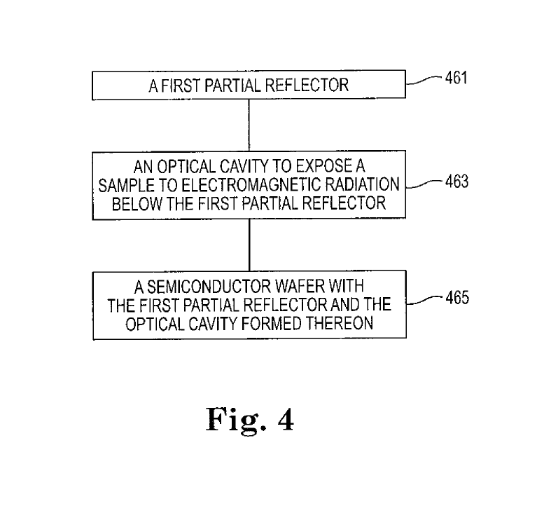

FIG. 4 is a block diagram illustrating an example of a portion of a CES apparatus according to the present disclosure. In accordance with the CES apparatus described herein, there is a first partial reflector, as shown in block 461. As shown in block 463, the apparatus includes an optical cavity to expose a sample to electromagnetic radiation below the first partial reflector. As shown in block 465, the apparatus includes a semiconductor wafer with the first partial reflector and the optical cavity formed thereon

In some examples, the CES apparatus can include a second partial reflector (e.g., 113) positioned below the first partial reflector (e.g., 112) and/or the optical cavity (e.g., 123), as illustrated in FIG. 1. Alternatively or in addition, the CES apparatus can include a complete reflector (e.g., 224) positioned below the first partial reflector (e.g., 212) and/or the optical cavity (e.g., 223), as illustrated in FIG. 2. In various examples, the CES apparatus can include the first partial reflector and another reflector, each on opposite sides of the optical cavity, forming a resonance chamber for electromagnetic radiation emitted by an electromagnetic source, as described herein. The effective path length of electromagnetic radiation in the optical cavity can become greater than the physical length of the optical cavity by reflecting multiple times within the optical cavity, as described herein.

Hence, an example of a system for CES, as described herein, can include an optical cavity (e.g., 123) with an electromagnetic radiation source (e.g., 111) to emit electromagnetic radiation introduced (e.g., 119) into the optical cavity (e.g., 123). In various examples, the system for CES can include a first partial reflector (e.g., 112) to partially reflect electromagnetic radiation from the electromagnetic radiation source (e.g., 111) within the optical cavity, a sample delivery device (e.g., 350) to deliver a sample (e.g., 316) into the optical cavity. In various examples, the system can include a semiconductor wafer (e.g., 115) with the optical cavity (e.g., 123) formed thereon. In various examples, the system can include an electromagnetic radiation detector (e.g., 114) to detect residual electromagnetic radiation (e.g., 122) following absorption of a fraction of the electromagnetic radiation by the sample (e.g., 116), as described herein.

In some examples, the system can include the emitted electromagnetic radiation (e.g., 117) and the residual electromagnetic radiation (e.g., 122) being substantially at the same frequency. In some examples, the electromagnetic radiation source (e.g., 111) can emit electromagnetic radiation introduced (e.g., 119) into the optical cavity (e.g., 123) at a particular frequency and/or range of frequencies. In various examples, the sample (e.g., 116) can absorb a portion of the electromagnetic radiation (e.g., 119) at the particular frequency and/or range of frequencies within the optical cavity (e.g., 123). In addition, a residual portion of the electromagnetic radiation (e.g., 122) can be detected by the detector (e.g., 114) configured to detect the particular frequency and/or range of frequencies. By so doing, an absorption spectrum at the particular frequency and/or range of frequencies can be determined (e.g., by comparison to results obtained with a vacant optical cavity and/or with a control sample in the optical cavity).

In some examples, the system can include a second partial reflector (e.g., 113) positioned above the electromagnetic radiation detector (e.g., 114) and below the optical cavity (e.g., 123). Alternatively, in some examples, the system can include a complete reflector (e.g., 224) positioned below the optical cavity (e.g., 223) and the electromagnetic radiation detector (e.g., 226).

In various examples, the system can include an array of such systems for CES. That is, small size and/or low unit cost of the CES apparatus can make arrays including multiple CES apparatuses practical. In some examples, individual CES apparatuses can be combined into an array to allow for analysis of multiple samples, to enable pattern recognition and/or to enhance sensitivity and/or reproducibility. For example, each CES apparatus within the array can be designed to be resonant, as described herein, with and/or detect specific frequencies (e.g., by varying the configuration of and/or distance between the one or more partial reflectors, complete reflector, and/or cavity walls associated with the optical cavity) to enable acquisition of an absorption spectrum across a number of light frequencies. This can enable rapid identification of a chemical and/or biological species.

Accordingly, in some examples, each of the optical cavities within an array can be resonant with electromagnetic radiation from a number of electromagnetic radiation sources. In some examples, the optical cavity can be at a vacuum. That is, the amount of pressure inside the optical cavity can be lower than the pressure outside the optical cavity.

In some examples, arrays can include substantially similar devices for reliability-through-redundancy applications. In some examples, redundancy can include circuitry that places a second CES apparatus in the array on-line upon failure of a first CES apparatus. By way of example, the second CES apparatus can be coupled (e.g., electrically) in series or in parallel with the first CES apparatus. In some examples, the circuitry can identify failed components for an operator.

In some examples, arrays can be formed by methods sufficient to allow high throughput and/or substantially continuous processing of the arrays. By way of example and not limitation, in some examples this can include roll to roll processing and/or large scale formation using techniques such as those described herein in conjunction with a semiconductor wafer of a size sufficient to allow multiple optical cavities to be formed thereon. Consequently, in some examples, the formed arrays can be separated into smaller arrays and/or individual optical cavities.

The present disclosure includes apparatuses, systems, and methods for implementing and forming CES. CES can be used for the applications described in the present disclosure, although the CES as described herein is not limited to such applications. It is to be understood that the above description has been made in an illustrative fashion and not a restrictive one. Although specific examples for apparatuses, systems, and methods have been illustrated and described herein, other equivalent component arrangements and/or structures conducive to CES can be substituted for the specific examples shown herein without departing from the spirit of the present disclosure.

1. A cavity enhanced spectroscopy apparatus, comprising:
a first partial reflector;
an optical cavity to expose a sample to electromagnetic radiation positioned below the first partial reflector; and
a semiconductor wafer with the first partial reflector and the optical cavity formed thereon.

2. The apparatus of claim 1, comprising a second partial reflector positioned below the first partial reflector and the optical cavity.

3. The apparatus of claim 1, comprising a complete reflector positioned below the first partial reflector and the optical cavity.

4. The apparatus of claim 1, wherein the first partial reflector and another reflector, each on opposite sides of the optical cavity, form a resonance chamber for electromagnetic radiation emitted by an electromagnetic source.

5. A method of forming a cavity enhanced spectroscopy apparatus, comprising:
providing a number of electromagnetic radiation sources;
forming an optical cavity, wherein forming the optical cavity comprises:
forming a first substrate on an upper surface of a semiconductor wafer;
forming the optical cavity above the first substrate; and
forming a second substrate above the optical cavity.

6. The method of claim 5, wherein forming the optical cavity comprises forming a spacer on an upper surface of the first substrate.

7. The method of claim 5, wherein forming the optical cavity comprises forming a sacrificial layer on an upper surface of the first substrate, wherein the sacrificial layer is smoothed and at least partially removed.

8. The method of claim 5, wherein forming the first substrate comprises:
forming a first dielectric on the upper surface of the semiconductor wafer;
forming a partially reflective material on an upper surface of the first dielectric; and
forming a second dielectric on an upper surface of the partially reflective material.

9. The method of claim 5, wherein forming the second substrate comprises:
forming a third dielectric on an upper surface of the sacrificial layer;
forming a partially reflective material on an upper surface of the third dielectric; and
forming a fourth dielectric on an upper surface of the partially reflective material.

10. A system for cavity enhanced spectroscopy, comprising:
an optical cavity;
an electromagnetic radiation source to emit electromagnetic radiation into the optical cavity;
a first partial reflector to partially reflect electromagnetic radiation from the electromagnetic radiation source within the optical cavity;
a sample delivery device to deliver a sample into the optical cavity;
a semiconductor wafer with the optical cavity formed thereon; and
an electromagnetic radiation detector to detect residual electromagnetic radiation following absorption of a fraction of the electromagnetic radiation by the sample.

11. The system of claim 11, wherein the emitted electromagnetic radiation and the residual electromagnetic radiation are substantially at the same frequency.

12. The system of claim 11, comprising a second partial reflector positioned above the electromagnetic radiation detector and below the optical cavity.

13. The system of claim 11, wherein a dielectric material is located on the first partial reflector.

14. The system of claim 11, wherein the system comprises an array of such systems for cavity enhanced spectroscopy.

15. The system of claim 14, wherein each of the optical cavities is resonant with electromagnetic radiation from a number of electromagnetic radiation sources.
